(19) United States
(12) Patent Application Publication
(10) Pub. No.: US 2004/0032959 A1
(43) Pub. Date: Feb. 19, 2004

(54) Method of acoustically correct bass boosting and an associated playback system

(76) Inventors: Christoph Montag, Hildesheim (DE); Joerg Sahrhage, Hildesheim (DE)

Correspondence Address: KENYON & KENYON, ONE BROADWAY, NEW YORK, NY, 10004, US

(21) Appl. No.: 10/454,988

(22) Filed: Jun. 4, 2003

(30) Foreign Application Priority Data
Jun. 6, 2002 (DE) 102 25 145.2

(51) Int. Cl. H03G 5/00

(52) U.S. Cl. 381/103; 381/98

(57) ABSTRACT

A method of acoustically correct boosting of the bass level of a playback system for audio signals by adjusting at least one filter parameter of at least one bass-boosting filter unit which is provided for the playback system and is assigned in particular to at least one digital equalizer that is provided with the playback system so that excessive boosting of bass level is prevented is described. This involves adjusting at least one filter parameter of the bass-boosting filter unit so that the boost in the bass level is reduced with an increase in the cut-off frequency and/or with an increase in the mid-frequency of the bass-boosting filter unit such that the isophones in the remaining reproducible bass frequency range are not exceeded.

### FIELD OF THE INVENTION

The present invention relates to a method of acoustically correct boosting of the bass level of a playback system for audio signals by adjusting at least one filter parameter of at least one bass-boosting filter unit assigned to the playback system, this filter unit being assigned in particular to at least one digital equalizer provided for the playback system.

The present invention also relates to a playback system for audio signals, in particular for performing a method of the type defined above, which is provided for acoustically correct boosting of the bass level by adjusting at least one filter parameter of at least one bass-boosting filter unit, which is provided for the playback system and in particular is provided for at least one digital equalizer provided for the playback system, having at least one loudspeaker unit, and at least one audio processor, which contains the equalizer, is situated in the signal path between at least one signal source and the loudspeaker device, and is connected by at least one control bus to at least one control processor.

### BACKGROUND INFORMATION

The present invention is based on conventional car radio equipment and on 21C technology, in which the audio playback device and its tuner in particular are provided with a digital receiver unit in particular, e.g., a digital receiver (known as a “digiceiver”). In other words, this means that the high-frequency signal of the IF (intermediate frequency) stage at 10.7 MHz, for example, is converted into bits and bytes as early as in the reception part of the tuner, and following this, it is processed further consistently on a digital level up to the output stages.

In the case of such car radio equipment, two or three freely programmable audio filters, for example, are integrated into the signal path. These digital parametric equalizers (“DPE”) are available to the user to compensate for inadequacies in the acoustics in the interior of the vehicle. The user is able to adjust each filter with respect to certain filter parameters, e.g., with respect to damping, and with respect to quality, i.e., filter width, with respect to the mid-frequency and/or with respect to the gain to compensate for overshooting and holes, as they are called, in the acoustic frequency response of the interior of the vehicle.

In conjunction with the acoustic frequency response or, in more general terms, the loudness perception of the human ear, it should be noted that this loudness perception is different over the audible frequency range. In other words, the sensitivity of the human ear is not constant over all frequencies but instead decreases toward high frequencies and declines to an even greater extent toward low frequencies. This effect occurs even more with a drop in sound pressure level, and as shown in FIG. 1, it is described in the literature by curves of equal loudness (known as isophones) as a function of sound pressure level L (in dB=decibel) over frequency F (in Hz=hertz) (see also International Standardization Organization (“ISO”) 226).

For example, a much higher'sound pressure level is required to achieve the same loudness impression at an audio frequency of 100 hertz as at a frequency of 1 kilohertz. This relationship is also shown by the diagram of the above-mentioned lines of equal loudness in a sound pressure/frequency diagram (see FIG. 1, where the speech range has been labeled as 80, the music range as 82 and the threshold of audibility as 84).

To compensate for this effect, audio signal playback systems often have a device for selective boosting of the bass level at a low playback loudness. In many systems, the highs are also boosted slightly. This device, known as an “acoustically correct loudness correction” or simply “loudness control” is supposed to maintain a constant loudness level of the audio signal perceived by the listener regardless of playback loudness over the entire audible frequency spectrum, i.e., to ensure a spectrally balanced sound.

Generally, first- or second-order recursive filters are used for this purpose; they may be configured either as resonance filters or as shelving filters. Resonance filters are characterized by boost G, quality Q and mid-frequency f₀ parameters and are suitable for boosting any narrow frequency band, but shelving filters boost the entire frequency range above or below a certain cut-off frequency f_{c}, the steepness of the filter being determined only by the order of the filter.

One problem frequently encountered in implementing an acoustically correct loudness correction is that the loudspeaker systems used do not adequately reproduce the low frequencies which should be boosted. The boost in sound level, which increases sharply at extremely low frequencies, has no acoustic effect at all under these circumstances and also results in unnecessary overloading of the power amplifier stages and loudspeakers, which is manifested at least in an increased harmonic distortion.

For this reason, some audio playback systems offer the option of shifting the filter cut-off frequency f_{c} and/or filter mid-frequency f₀ upward until there is an audible effect. However, with conventional playback systems, selective boosting of levels according to FIG. 2A, regardless of the selected filter cut-off frequency f_{c} and/or regardless of the selected filter mid-frequency f₀ is controlled according to a fixedly defined function based only on loudness S set by the user on the playback device.

However, such a traditional procedure does not do justice to psychoacoustic findings for the case when cut-off frequency f_{c} and/or mid-frequency f₀ are boosted by the bass-boosting filter, because in this case the low frequencies are boosted to an excessive extent.

### SUMMARY

An object of the present invention is to improve upon a conventional method and playback system in such a way as to avoid excessive boosting of the bass.

According to example embodiments of the present invention, a method of acoustically correct correction of the frequency response in the bass frequency range is provided, in which a psychoacoustically appropriate boosting of bass level P is achieved while minimizing system overload at the same time due to the fact that set filter cut-off frequency f_{c} and/or set filter mid-frequency f₀ is/are additionally taken into account in a suitable manner. Therefore, this yields an acoustically correct boosting of the bass level as a function of the filter use frequency.

This may be achieved according to the example embodiments of the present invention by providing a method of preferably automatic optimization of the acoustically correct boosting of bass level P in an audio playback system in which the filter parameter(s) of the bass-boosting filter unit is/are adjusted so that boosting of bass level P decreases with an increase in cut-off frequency f_{c} and/or with an increase in mid-frequency f₀ of the bass-boosting filter unit, so that the isophones are not exceeded in the remaining reproducible bass frequency range.

Thus, by using the example embodiments of the present invention, the user is relieved of the difficult task of adjusting the bass-boosting filter unit(s) to the specific acoustics of his/her vehicle interior.

If maintaining a functional relationship between mid-frequency f₀ of the bass-boosting filter unit and acoustically correct boosting of bass level P is not associated with a manual adjustment but instead is associated with an automatic determination of this mid-frequency f₀, then according to one preferred embodiment, the bass-boosting filter unit will perform the following functions before adjusting the at least one filter parameter:

first it determines the acoustic frequency response of the interior of the vehicle,

then it determines the average sound pressure level and

next it determines a cut-off frequency below which the sound pressure drops below a sound pressure threshold value based on the average sound pressure level.

In detail, first the frequency response of the given audio playback system is determined with the help of suitable measures. Following this, the measured frequency response is analyzed with regard to the efficiency of the playback system in the low-frequency range.

From the measured frequency response, it is possible to determine first the average sound pressure level. Following that, the frequency point in the low frequency range below which the sound pressure drops below a certain limit value, based on the average sound pressure, e.g., approximately three decibels, is determined.

A bass-boosting filter is then adjusted precisely, so that the isophones are not exceeded in the remaining reproducible bass frequency range. This is achieved by the fact that the boost in bass level P is reduced with an increase in cut-off frequency f_{c} and/or with an increase in mid-frequency f₀ of the bass-boosting filter unit, thus yielding a set of level characteristic curves as a function of filter cut-off frequency f_{c} (e.g., shelving filter) or as a function of filter mid-frequency f₀ (e.g., resonance filter).

In this way it is possible to ensure that the boost in bass level will in fact be acoustically effective without overloading the system, because in the case of the embodiment as at least one shelving filter, the frequency response of the bass-boosting filter remains constant below cut-off frequency f_{c} or it drops back below mid-frequency f₀ in the case of the embodiment as at least one resonance filter.

In addition, an example playback system is provided, including a noise generator allowing a noise signal to be sent via the equalizer provided with the bass-boosting filter unit for acoustically correct boosting of bass level P, i.e., for preferably automatic adjustment of the at least one bass-boosting filter unit.

In addition, the control processor has means by which the filter parameters are adjustable, so that the equalizer has a small bandwidth bandpass characteristic, the mid-frequency being variable over the audio spectrum.

At least one microphone equipped with analyzer means is provided for detecting the signal emitted by the loudspeaker device into the interior of the vehicle and determining the frequency response.

Finally, the control processor also has means allowing the filter parameters to be adjusted, taking into account the measured frequency response.

It has been recognized that because of their programmability, the equalizers to be calibrated may be used first to determine the acoustic frequency response of the interior of the vehicle, before it is possible to determine a cut-off frequency below which the sound pressure falls below a sound pressure threshold level based on the average sound pressure.

In addition, it has been recognized according to the present invention that for determination of the acoustically correct boosting of bass level P, filter cut-off frequency f_{c} and/or filter mid-frequency f₀ of the bass-boosting filter or loudness filter should be taken into account in a suitable manner in addition to loudness setting S. As shown by FIG. 2B, the slope of the gain characteristic of the bass-boosting filter is reduced with an increase in filter cut-off frequency f_{c} or filter mid-frequency f₀ in such a way that the isophones in the remaining reproducible bass frequency range are not exceeded, and thus excessive bass boosting is avoided.

The relationship between the filter mid-frequency/cut-off frequency and loudness setting S as input variables and the resulting bass boosting as the output variable is described by a mathematical function, which may be continuous or may involve stages in a manner according to the present invention, depending on the particular givens of the case. Thus, as a result, the acoustically correct bass boosting is automatically optimized by adjusting the filter parameters of the bass-boosting filter unit as a function of cut-off frequency f_{c} and/or mid-frequency f₀.

There is thus a functional relationship between cut-off frequency f_{c}/mid-frequency f₀ of the loudness filter and the required gain as well as the required quality which is appropriate for a truly acoustically correct loudness correction. Maintaining this relationship may, but need not, be associated with automatic determination of cut-off frequency f_{c} and/or mid-frequency f₀.

In other words, this means that the functional relationship described above should be maintained in manual adjustment of cut-off frequency f_{c} and/or mid-frequency f₀ as well as in automatic adjustment of cut-off frequency f_{c} and/or mid-frequency f₀. In the latter case, the feature whereby the boost in bass level P is reduced with an increase in cut-off frequency f_{c} and/or with an increase in mid-frequency f₀ of the bass-boosting filter unit, so that the isophones in the remaining reproducible bass frequency range are not exceeded, is linked in a manner essential to the present invention with the feature whereby the filter parameter(s) of the bass-boosting filter unit is/are automatically adjusted so that the mid-frequency of the bass-boosting filter unit is just above the cut-off frequency determined.

Therefore, in a synergistic manner, excessive boosting of bass level P is prevented while at the same time automatic optimization of acoustically correct bass boosting is achieved. Furthermore, it has been recognized according to the present invention that optimization of acoustically correct boosting of bass level P may be performed by the control processor, which is present in the car radio device anyway, with the help of suitable additional software.

Thus, as a result, as part of the present invention, no additional audio module having a digital signal processor is necessary, but instead this requires only a microphone circuit, an amplifier circuit and a rectifier circuit, which are connected to the analog/digital (“a/d”) converter unit provided in the control processor. Therefore, only a very minor increase in expenditure is necessary in terms of hardware and software and ultimately cost for the adjustment of the filter parameters as proposed according to the present invention with respect to bass boosting.

There are various possibilities for determining the acoustic frequency response of the interior of the vehicle as part of the present method. According to one advantageous embodiment, the loudspeaker device of the playback system is triggered by a series of bandpass noise signals having different mid-frequencies. The frequency bands set in the form of a bandpass noise signal cover the entire audio spectrum.

The frequency response to be determined will now be determined in the form of frequency measurement points for the individual frequency bands. The sound level of the signal can easily be determined as the frequency measurement point for a certain frequency band, the signal in this case being emitted by the loudspeaker device into the interior of the vehicle.

From the standpoint of minimizing both hardware and software complexity, it has proven advantageous for the bandpass noise signals for determining the acoustic frequency response of the interior of the vehicle to be generated with the help of the equalizer itself which is to be adjusted. Since both the mid-frequency and quality of the equalizer are freely programmable, the filter parameters may be adjusted so as to yield a bandpass characteristic having a narrow bandwidth at a defined mid-frequency for the equalizer.

The equalizer then generates the desired bandpass noise signal from a noise signal supplied to it and/or it generates a sequence of bandpass noise signals covering the entire audio spectrum.

If the filter parameters are automatically set by a plurality of digital equalizers, it may be advantageous to determine the filter parameters of the individual equalizers in succession by using the previously adjusted equalizer(s) at the measured frequency response before determining the filter parameters of an equalizer.

Finally, the present invention relates to the use of the method of the type described above and/or the playback system of the type described above for audio signals in at least one means of locomotion, in particular in the interior of at least one motor vehicle.

As explained in detail above, there are various possibilities for configuring and improving upon the teaching of the present invention in an advantageous manner.

### BRIEF DESCRIPTION OF THE DRAWINGS

FIG. 1 shows a diagram for curves of equal loudness (i.e., isophones) plotted as sound pressure level as a function of frequency; standardized according to the ISO.

FIG. 2A shows a schematic diagram of a sound level characteristic curve (bass boost P plotted as a function of loudness S) of a conventional acoustically correct bass level correction according to the related art.

FIG. 2B shows a schematic diagram of a set of level characteristic curves (bass boost P plotted as a function of loudness S) of an acoustically correct bass correction by the method according to the present invention, these curves being formed as a function of the filter cut-off frequency and/or the filter mid-frequency.

FIG. 3 shows a schematic block diagram (flow chart) of an exemplary embodiment for a method according to the present invention.

FIG. 4 shows a schematic diagram (block diagram) of an exemplary embodiment of a playback system according to the present invention, provided for implementing the method according to FIG. 3.

### DETAILED DESCRIPTION

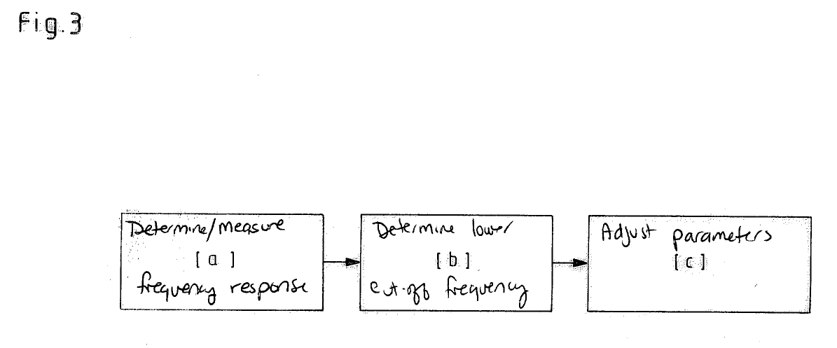

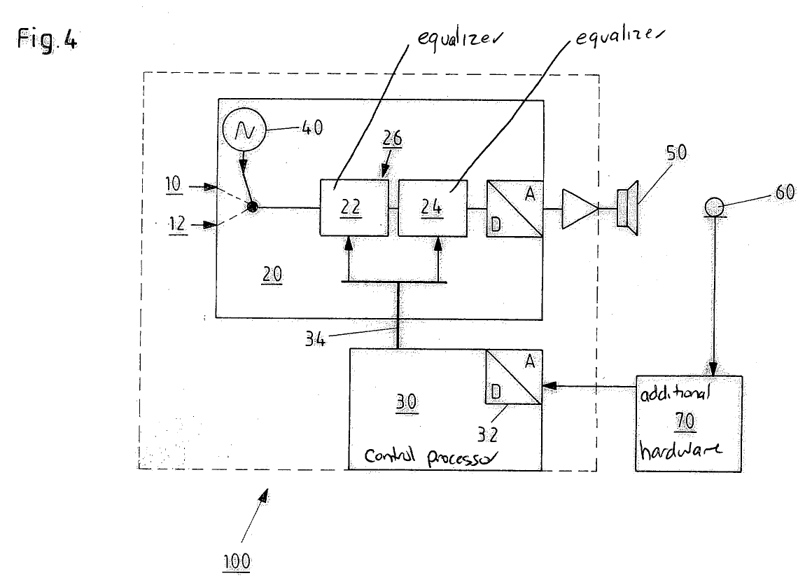

FIG. 3 shows an example operating principle of a playback system 100 according to the present invention illustrated on the basis of FIG. 4.

Audio playback system 100 illustrated in FIG. 4 is used for playback of audio signals in the interior of a vehicle, where the audio signals may be generated by different audio sources 10, 12, e.g., a compact disc (“cd”), a radio or the like.

Playback system 100 has a loudspeaker unit 50 and an audio processor 20, which is situated in the signal path between audio sources 10, 12 and loudspeaker device 50 and has two freely adjustable digital equalizers 22, 24 via which the signals of different audio sources 10, 12 are sent to loudspeaker device 50. More than two equalizers 22, 24 may, of course, also be provided here.

For adjusting the filter parameters, in particular for adjusting mid-frequency f₀, a control processor 30 sends suitable filter parameters via a control bus 34 to audio processor 20.

For determining and/or measuring the frequency response of the present audio system in the interior of a vehicle (method step a according to FIG. 3), playback system 100 also has a noise generator 40 by which a noise signal may be supplied to equalizers 22, 24. Noise generator 40 here is implemented as additional software in audio processor 20 which may be initialized as needed via control processor 30.

As an alternative, the noise signal may also be generated by an external sound source as an additional audio source, e.g., with the help of a corresponding cd or with the help of a suitably tuned tuner.

In addition, control processor 30 has means by which the filter parameters may be adjusted, so that equalizers 22, 24 have a narrow bandwidth bandpass characteristic, i.e., with a quality on the order of 8, mid-frequency f₀ being variable over the audio spectrum. In this way, loudspeaker device 50 may be triggered with a bandpass noise signal with the help of noise generator 40 and via equalizers 22, 24.

When the calibration of equalizers 22, 24 has been started, e.g., by pressing a pushbutton, control processor 30 varies the filter parameters in a defined chronological order, so that mid-frequency f₀ of the bandpass filter decreases, e.g., in the third-octave interval from the highest to the lowest frequency to be set.

The signals, which are then emitted via loudspeaker device 50 into the interior of the vehicle, are picked up with the help of a microphone 60 and analyzed by suitable analyzer means 70 for determining the frequency response in the interior of the vehicle.

To do so, the signals detected by microphone 60 are amplified, logarithmized and rectified in an optical amplifier circuit, so that a direct voltage is applied at the output of this circuit. This direct voltage is proportional to the sound level, i.e., the sound pressure in the interior of the vehicle for the frequency band set by the particular bandpass noise signal. Due to this tuning of equalizers 22, 24, the sound level for the entire audio spectrum is detected.

The direct voltage representing the sound level is sampled by an a/d converter 32 of control processor 30, so that after tuning all the frequencies and frequency bands to be measured using the corresponding voltage values, an accurate picture of the acoustic frequency response of the interior of the vehicle is available to control processor 30. The term frequency response is used here to refer only to the absolute value of the frequency response, i.e., the amplitude response rather than the phase response.

Then in a second method step (b) (see FIG. 3), a lower cut-off frequency below which the sound pressure drops below a sound pressure threshold value based on the average sound pressure level is determined in control processor 30.

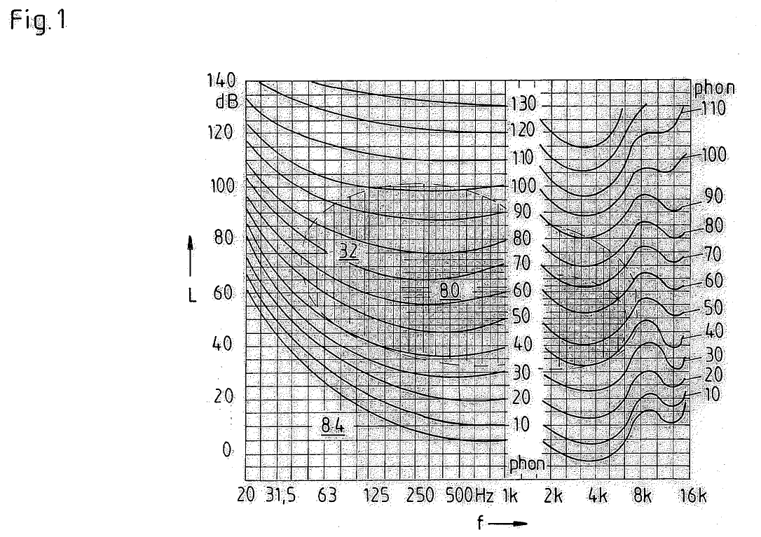

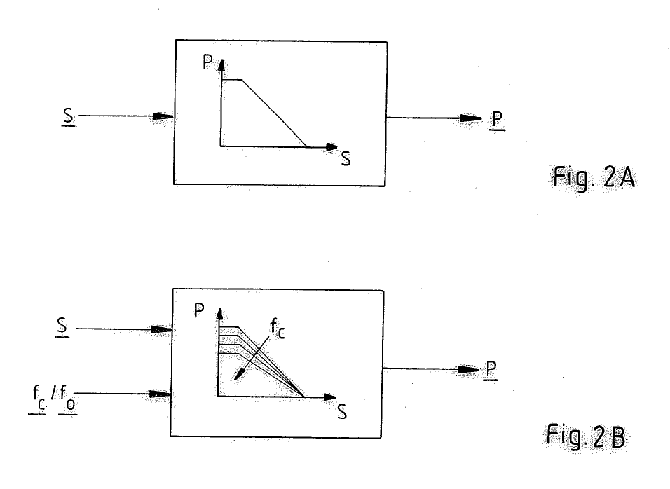

In a final method step (c) (see FIG. 3), the filter parameters, in particular boost G, quality Q and mid-frequency f₀ of bass-boosting filter unit 26, are adjusted automatically, the boost in bass level P being reduced (see FIG. 2B) with an increase in cut-off frequency f_{c} and/or an increase in mid-frequency f₀ of bass-boosting filter unit 26, so the isophones (see FIG. 1) in the remaining reproducible bass frequency range are not exceeded.

As a result, this yields automatic optimization of an acoustically correct boosting of the bass level by adjusting the filter parameters of bass-boosting filter unit 26 as a function of cut-off frequency f_{c} and/or mid-frequency f₀. There is thus a functional relationship between cut-off frequency f_{c} and/or mid-frequency f₀ of loudness filter 26 and the required gain as well as the required quality which is appropriate for a truly acoustically correct correction of loudness.

Maintaining this relationship may, but need not, be associated with an automatic determination of cut-off frequency f_{c} and/or mid-frequency f₀. In other words, this means that the functional relationship described above should be maintained in manual adjustment of cut-off frequency f_{c} and/or mid-frequency f₀ of bass-boosting filter unit 26 and also in automatic adjustment of cut-off frequency f_{c} and/or mid-frequency f₀ of bass-boosting filter unit 26.

In a manner according to the present invention, the feature whereby the boosting of bass level P is reduced with an increase in cut-off frequency f_{c} (via, e.g., a shelving filter) and/or with an increase in mid-frequency f₀ (via, e.g., a resonance filter) so that the isophones are not exceeded in the remaining reproducible bass frequency range is linked with the feature whereby the filter parameter(s) of bass-boosting filter unit 26 is/are automatically adjusted so that mid-frequency f₀ of bass-boosting filter unit 26 is just above the cut-off frequency determined. Therefore, excessive boosting of the bass level is prevented, but also acoustically correct boosting of the bass level is automatically optimized in a synergistic manner.

The total additional complexity in comparison with a car radio in which the equalizers are not automatically adjustable includes additional hardware 40 and/or additional software for generating a noise signal, additional software in control processor 30 which takes over the sequence control function of the calibration procedure (method step a; see FIG. 3) and determination of the best filter parameter setting(s), and it also includes additional hardware 70 for the amplification, logarithmization and rectification of the signals of microphone 60.

To determine the best possible settings of the filter parameters, normalized model equalizer curves of different qualities may also be stored in audio processor 20.

In conclusion, it should also be pointed out that by measuring the loudness function (<->loudness optimization on audio playback system 100), it is readily possible to demonstrate the automatic acoustically correct boosting of bass level described above as a function of mid-frequency f₀ and/or cut-off frequency f_{c} of loudness filter 26 in a product 100 having an adjustable loudness filter cut-off frequency and/or mid-frequency, because first of all, a frequency response measurement must be activatable by the user (e.g., operating instructions) and second, the optimization is verifiable by measuring the loudness curves according to frequency response measurements in different audio systems.

What is claimed is:

1. A method of acoustically correct boosting of a bass level of a playback system for audio signals comprising:
adjusting at least one filter parameter of at least one bass-boosting filter unit which is provided for the playback system and is assigned to at least one digital equalizer associated with the playback system), wherein the at least one filter parameter of the bass-boosting filter unit is adjusted so that a boost in the bass level is reduced with at least one of: i) an increase in a cut-off frequency of the bass-boosting filter unit, and ii) an increase in the mid-frequency of the bass-boosting filter unit, so that isophones in a remaining reproducible bass frequency range are not exceeded.

2. The method as recited in claim 1, further comprising:
prior to adjusting the at least one filter parameter of the bass-boosting filter unit, determining an acoustic frequency response and an average sound pressure level, and determining a cut-off frequency below which a sound pressure level falls below a sound pressure threshold value based on the average sound pressure level.

3. The method as recited in claim 2, wherein the determining of the acoustic frequency response includes:
triggering at least one loudspeaker device of the playback system using a series of bandpass noise signals having different mid-frequencies in succession, frequency bands, each being set in the form of at least one bandpass noise signal, covering the entire audio spectrum; and
determining the acoustic frequency response in a form of frequency measurement points for each of the frequency bands, a sound level of a signal emitted by the loudspeaker device, being determined as the frequency measurement point for a certain frequency band.

4. The method as recited in claim 3, wherein the bandpass noise signals for determining the acoustic frequency response are generated by the equalizer in that at least one noise signal is supplied to the equalizer, and the at least one filter parameter of the bass-boosting filter unit is adjusted to yield a narrow bandwidth bandpass characteristic at a defined mid-frequency for the equalizer.

5. The method as recited in claim 1, wherein the at least one filter parameter of the bass-boosting filter unit is automatically adjusted so that the mid-frequency of the bass-boosting filter unit is just above the determined cut-off frequency.

6. The method as recited in claim 1, wherein the at least one filter parameter is automatically adjusted by at least two digital equalizers, wherein filter parameters of the individual equalizers are determined in succession by applying previously adjusted equalizers to the determined frequency response before determining filter parameters of the equalizers.

7. A playback system for audio signals, comprising:
at least one loudspeaker device;
at least one audio processor including at least one digital equalizer, the at least one audio processor being situated in a signal path between at least one signal source and the loudspeaker device, and being connected to the control processor via a control bus;
at least one noise generator via which at least one noise signal is supplied to the at least one equalizer;
at least one bass-boosting filter unit assigned to the at least one equalizer; and
at least one microphone equipped with an analyzer configured to detect a signal emitted by the loudspeaker device and to determine a frequency response thereof;
wherein the control processor includes means by which at least one filter parameter of the bass-boosting filter unit is adjusted so that the at least one equalizer has a narrow bandwidth bandpass characteristic, a mid-frequency being variable over an audio spectrum, and wherein the control processor includes an adjustment device by which the at least one filter parameter is adjusted, taking into account the determined frequency response.

8. The playback system as recited in claim 7, wherein the noise generator is at least one of: i) implemented in the audio processor, and ii) implemented in a form of an additional external signal source.

9. The playback system as recited in claim 7, wherein the analyzer includes an amplifier to amplify the signal, a device configured to logarithmize the signal, and a device to rectify the signal.

10. The playback system as recited in claim 7, wherein the playback system is provided in a motor vehicle.

11. The method as recited in claim 1, further comprising:
providing the playback system in a motor vehicle.
